(19) United States
(12) Patent Application Publication
(10) Pub. No.: US 2010/0040169 A1
(43) Pub. Date: Feb. 18, 2010

(54) CODING METHODS AND SYSTEMS FOR IMPROVED ERROR MARGINS

(75) Inventor: Aliazam Abbasfar, Sunnyvale, CA (US)

Correspondence Address: PVF -- RAMBUS, INC.;c/o PARK, VAUGHAN & FLEMING, LLP, 2820 FIFTH STREET, DAVIS, CA, 95618-7759, US

(73) Assignee: RAMBUS INC., Los Altos, CA (US)

(21) Appl. No.: 12/511,753

(22) Filed: Jul. 29, 2009

Related U.S. Application Data
(60) Provisional application No. 61/089,212, filed on Aug. 15, 2008.

(51) Int. Cl. H04L 27/00; H04L 27/06; H03M 7/00

(52) U.S. Cl. 375/295; 375/340; 341/106

(57) ABSTRACT

Each symbol in a sequence of codewords is expressed as a voltage level representative of a one or zero, and each codeword includes both levels. Sense amplifiers at the receiver compare all pairs of symbols in each codeword. Comparisons based upon like symbol values provide mid-range sensed voltages, and comparisons based upon disparate symbols values provide relatively higher or lower sensed voltages. Sampling the high and low voltages produces determinate sample values, whereas sampling the midrange voltage produces indeterminate sample values. Sampling the sensed voltages thus produces a mix of indeterminate and determinate values for each codeword. Codewords are selected such that the number and placement of the determinate sample values identify each codeword, and subsequent codewords are selected so the nodes supporting the high and low sensed voltages sampled to obtain the determinate sample values transitioned to their current voltage from either the intermediate voltage or did not transition.

### RELATED APPLICATION

This application hereby claims priority under 35 U.S.C. §119 to U.S. Provisional Application No. 61/089,212, entitled “Coding Methods and Systems for Improved Error Margins” by Aliazam Abbasfar, filed 15 Aug. 2008 (Atty. Docket No.: R-RA0637.Prov1.US).

### TECHNICAL FIELD

The present embodiments relate to techniques for communicating information. More specifically, the present embodiments relate to circuits and methods for encoding, communicating, and decoding information using multiple wires.

### BACKGROUND

Digital communication systems convey data over one or more conductors as varying voltages or currents that represent the data as series of symbols. Over a single wire, for example, relatively high and low voltages can be used to represent a logic one and a logic zero, respectively. The bandwidth of a given communication channel is generally limited by the speed at which the channel can transition between different types of symbols (e.g., between relatively high and low voltages). The time required to transition between symbols varies with symbol patterns, making it difficult to precisely place symbol boundaries at high data rates.

Communication systems are designed to accommodate some amount of variation in transition timing. A communication system's tolerance to such variations is called the ‘timing margin.’ In general, increased timing margins provide greater noise tolerance and, as a consequence, higher speed performance.

Conventional communication systems employ a wide variety of techniques to increase timing margins. In communication systems, such as single-wire systems, these techniques include coding and equalization (for example, using partial response equalization). However, many of these techniques involve using feedback, which increases the complexity and cost of the system. Moreover, feedback loops can cause error propagation when an error for a current bit or symbol leads to additional errors for subsequent symbols. Additionally, with or without feedback, there is always a demand for additional performance in communication systems. Therefore, there is a need more methods and systems that further improve timing margin and increase speed performance.

### BRIEF DESCRIPTION OF THE FIGURES

FIG. 1 is a state diagram illustrating an encoding technique in accordance with an embodiment that encodes two-bit data DQ[1:0] into one of ten, five-symbol codewords.

FIG. 2 depicts a system in which a transmitter includes an encoder that encodes two-bit data into codewords of five parallel symbols SM[4:0] in accordance with the state diagram of FIG. 1.

FIG. 3 is a table relating the ten odd and even states of the state diagram in FIG. 1 to the output voltages and logic values from the sense amplifiers and sampler of FIG. 2.

FIG. 4A is an eye pattern illustrating timing and voltage margin.

FIG. 4B is an eye pattern highlighting the improved timing and voltage margins provided by the embodiment of FIGS. 1-3.

FIG. 5 depicts a system in accordance with another embodiment that supports clock recovery.

### DETAILED DESCRIPTION

Disclosed are coding techniques that encode data into a sequence of symbol sets, or codewords, each of which defines a state. Each symbol in a given codeword is expressed as a voltage or current level representative of either a binary ‘1’ or a binary ‘0,’ and each codeword includes both of these symbol types. To decode the sequence of codewords, a collection of sense amplifiers compares all pairs of symbols for each codeword. Comparisons based upon like symbol values (e.g., two logic 0s) provide mid-range sensed voltages Vint, whereas comparisons based upon disparate symbols values (e.g., a logic 1 vs. a logic 0) provide relatively higher or lower sensed voltages ±Vp.

Sampling the high and low voltages ±Vp relative to a reference produces determinate sample values, whereas sampling the midrange voltage Vint relative to the reference produces indeterminate sample values. Thus, sampling the output voltages from the collection of sense amplifiers produces a mix of indeterminate and determinate sample values for each codeword. The codewords are selected such that the number and placement of the determinate sample values derived from each codeword are sufficient to uniquely identify the codeword, and the indeterminate sample values are ignored. Furthermore, each subsequent codeword is selected such that the nodes supporting the high and low sensed voltages ±Vp are sampled to obtain the determinate sample values transitioned to their current voltage ±Vp from either the intermediate voltage Vint or the same voltage for the preceding codeword, i.e., the nodes did not transition. Transitions from the intermediate voltage Vint to high/low voltages ±Vp take less time than the more extreme transitions between voltages −Vp and +Vp in differential signaling systems. The faster transitions provided by the instant coding technique provide dramatically improved timing margin over similar differential systems, and thus provide: increased data rates, reduced noise sensitivity, or both.

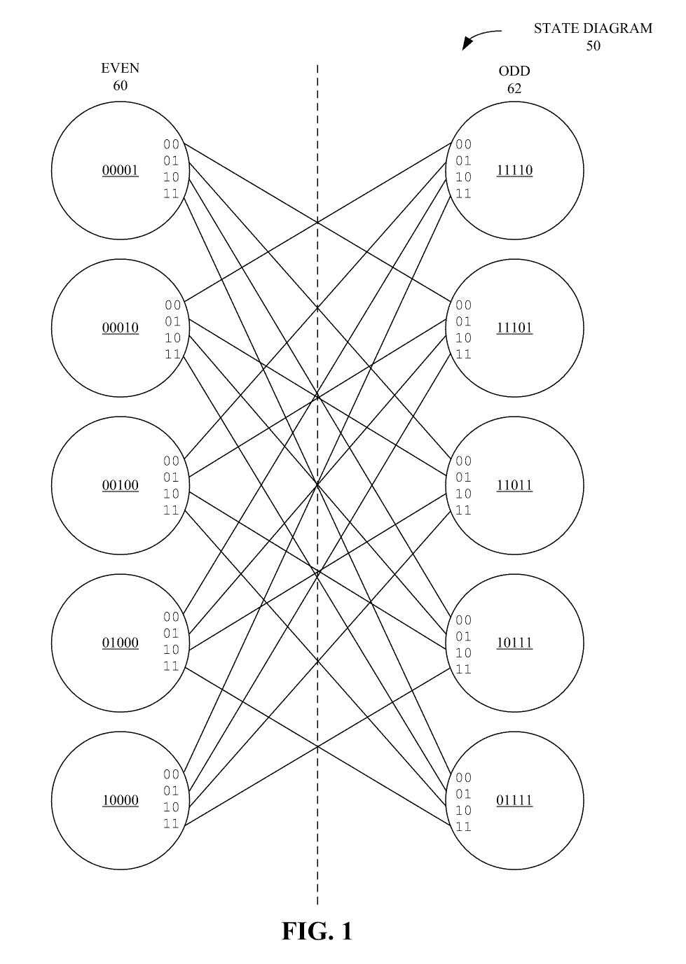

FIG. 1 presents a state diagram 50 illustrating an embodiment of an encoding technique that encodes two-bit data DQ[1:0] into one of ten, five-symbol codewords. Each codeword corresponds to one of the ten states, and the states are divided into complementary even and odd sets 60 and 62. Starting in a given state, each subsequent two-bit value DQ[1:0] is encoded into any but the complementary state in the other half of diagram 50. For example, assuming the state machine is in state 00001, the subsequent two bits of data are encoded to any but complementary state 11110. State transitions occur between the odd and even sets in successive time intervals.

State diagram 50 has a number of properties, the importance of which will become clear from the following discussion. First, each codeword has a mix of symbols types, logic 0s and 1s, at five symbols positions. Second, the symbols on the set of symbol positions with the minority symbol value are held constant between successive codewords. For example, in transitioning from state 00001 the minority symbol value is a logic 1 that shows up at the least significant bit position, and this position is held at logic 1 for any of the four possible subsequent odd states. The data is encoded into the majority symbol positions. Third, each successive codeword is selected from a subset of possible five-symbol codewords that produces the same number of symbol transitions from the prior codeword. Returning to the example of state 00001, each of the four possible subsequent states represents a codeword that includes exactly three symbol transitions. The current state is detected without knowledge of a prior state, so state errors do not propagate between codewords.

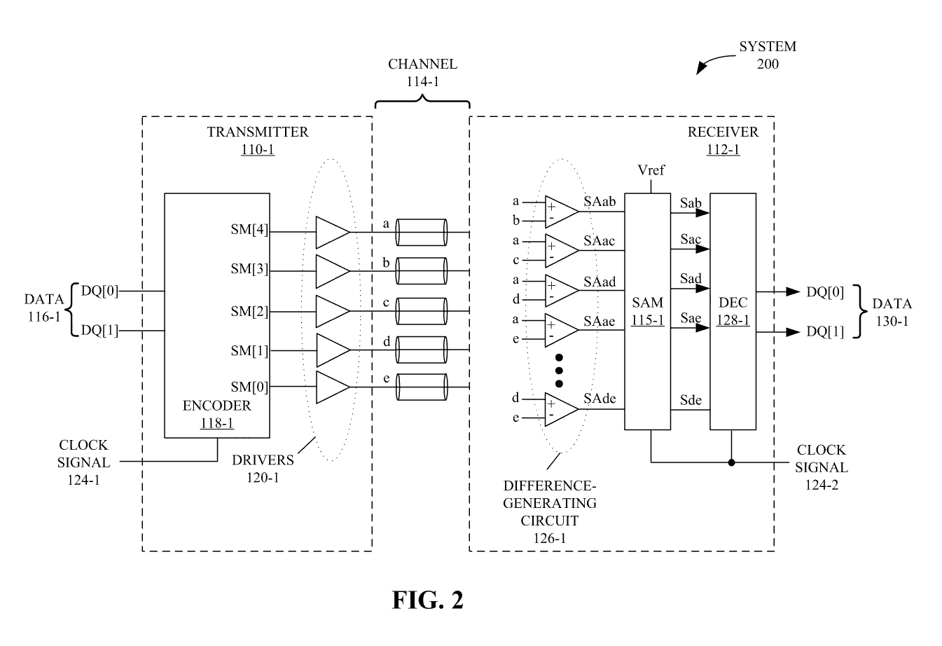

FIG. 2 depicts a system 200 in which a transmitter 110-1 includes an encoder 118-1 that encodes two-bit data 116-1 into codewords of five parallel symbols SM[4:0] based on state diagram 50 (FIG. 1). A clock signal 124-1 defines the time intervals separating issuance of the codewords. A set of drivers 120-1 drive symbols SM[4:0] onto respective parallel links a through e of a channel 114-1. Links a through e may be AC or DC coupled.

A receiver 112-1 coupled to channel 114-1 includes ten sense amplifiers, which are collectively termed a difference-generating circuit 126-1. The label for each sense amplifier output includes two lowercase characters that correspond to the compared input nodes. For example, amplifier output SAab results from a comparison of the symbols on nodes a and b from like-named links of channel 114-1. A sampler 115-1 samples the ten sense-amplifier output voltages relative to a reference voltage Vref and provides the resulting ten sample values S to a decoder 128-1. The label for each sample value includes two lowercase characters that correspond to the sense-amplifier outputs. For example, sample Sab is a sample of the sensed voltage SAab. A decoder 128-1 decodes the sample values from sampler 115-1 to recover the original data DQ[1:0] as output data 130-1. A clock signal 124-2 times the operation of sampler 115-1 and decoder 128-1.

In this embodiment, the sense amplifier output nodes range between symmetrical positive and negative voltages +Vp and −Vp. Comparisons based upon disparate symbols values (e.g., a logic 0 vs. a logic 1) provide high/low sensed voltages ±Vp at the sense-amplifier outputs. However, comparisons based upon like symbols provide intermediate sensed voltages Vint, which in this case are about zero volts (0 V). Thus, depending upon the values of the input symbol pair, the output voltage from a given sense amplifier tends toward one of voltages +Vp, 0 V, or −Vp. For example, output voltage SAab will transition toward:

voltage +Vp if the symbols on nodes a and b are respectively 1 and 0 (SM[4:3]=10);

voltage −Vp if the symbols on nodes a and b are respectively 0 and 1 (SM[4:3]=01); or

voltage 0 V if the symbols on nodes a and b are the same (SM[4:3]=00 or 11).

The nine remaining sense amplifiers behave similarly to produce intermediate and high/low voltages. Difference-generating circuit 126-1 thus produces a mixed set of intermediate and high/low sensed voltages for each codeword, and consequently for each state of state diagram 50 (FIG. 1). Other embodiments may have different high/low and intermediate voltage levels.

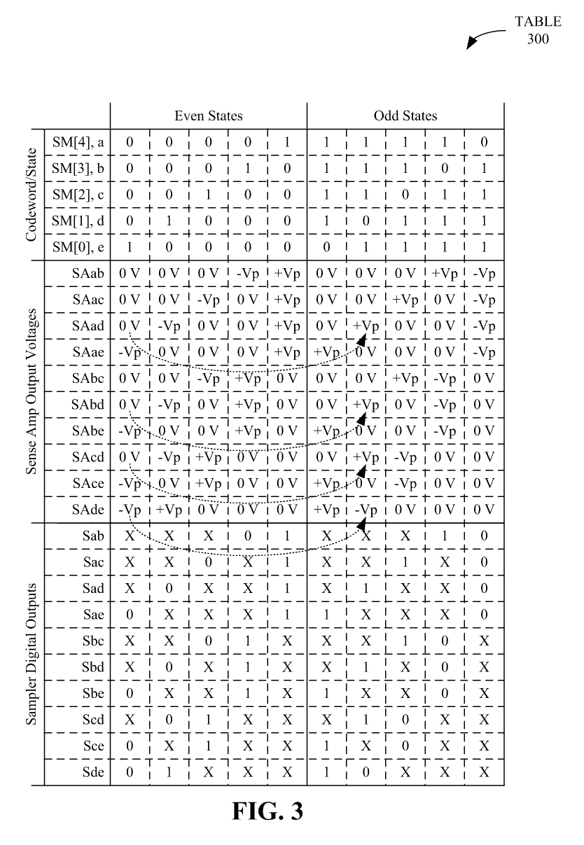

FIG. 3 presents a table 300 relating the ten odd and even states of state diagram 50 (FIG. 1) to the sense-amp output voltages SAxx and the sampler digital outputs Sxx. Each state provides four high/low voltages and six intermediate voltages. For example, in state 00001 output voltages SAae, SAbe, SAce, and SAde are low voltages −Vp and the remaining outputs are the intermediate voltage 0 V.

Sampler 115-1 samples the output voltages from the sense amplifiers relative to a reference voltage Vref that is between voltages ±Vp. Sampling the high/low voltage ±Vp relative to reference voltage Vref provides determinate logic-0 or logic-1 sample values that are representative of the encoded data. FIG. 3 identifies each determinate sample value with the appropriate logic value (0 or 1). Moreover, sampling the intermediate voltage 0 V provides indeterminate logic-0 or logic-1 sample values, which are labeled ‘X.’ Each codeword includes a mix of logic-0 and logic-1 values, so sampler 115-1 samples a mix of high/low and intermediate voltages, and consequently produces a mix of determinate and indeterminate sample values. Returning to the example of state 00001, the four high/low voltages −Vp from the sense amplifiers are interpreted as determinate logic 0 values and the remaining six samples are labeled ‘X.’

The states of state diagram 50 (FIG. 1), and consequently the codewords used to convey data, are selected such that the number and placement of the determinate sample values 0 and 1 derived from each codeword are sufficient to uniquely identify each codeword within the odd or even sets. For example, in table 300, if the state machine is an even state and Sae=Sbe=Sce=Sde=0, then the state must be 00001. The remaining even states are similarly identified by their respective deterministic sample values. The deterministic values of the odd states similarly identify each odd codeword/state within the odd subset of states. Knowledge of the deterministic values and whether the state is odd or even is thus sufficient to identify the state. Furthermore, because that state transitions are determined by the input data DQ[1:0], decoder 128-1 can decode a transition between two known states using simple logic to recover the data.

State machine 50 (FIG. 1) transitions between odd and even states for each successive codeword, and in so doing encodes two bits of data. The encoder and decoder know whether a given state is odd or even by, for example, always starting in a known state when sending a packet of data. Alternatively, whether a given state is odd or even can be sensed by considering the state of the channel. With reference to FIG. 3, and assuming logic 0 and logic 1 values are represented on each of links a through e as respectively low and high voltages, sensing an average voltage over the five links produces relatively low and high average voltages for the even and odd states.

FIG. 3 illustrates a property of the encoding technique the leads to dramatically improved timing margins. State machine 50 (FIG. 1) selects each subsequent state/codeword such that the high/low sensed voltages ±Vp sampled to obtain the determinate sample values either fail to transition between codewords or transition from the intermediate voltage 0 V. For example, state diagram 50 (FIG. 1) requires that state 00001 transition to one of states 11101, 11011, 10111, or 01111. Using the transition from state 00001 to state 11101 as an illustration, the target state 11101 provides deterministic voltages at sense amplifier outputs SAad, SAbd, SAcd, and SAde. As the dashed arrows indicate, the first three of these transitions begins at the intermediate voltage 0 V in the preceding codeword 00001 and the last does not transition at all. Transitions from the intermediate voltage 0 V to the high/low voltages ±Vp take less time than the more extreme transitions between voltages −Vp and +Vp in differential signaling systems. The faster transitions provided by the instant coding technique provide dramatically improved timing margin over similar differential systems, and thus afford increased data rates, reduced noise sensitivity, or both.

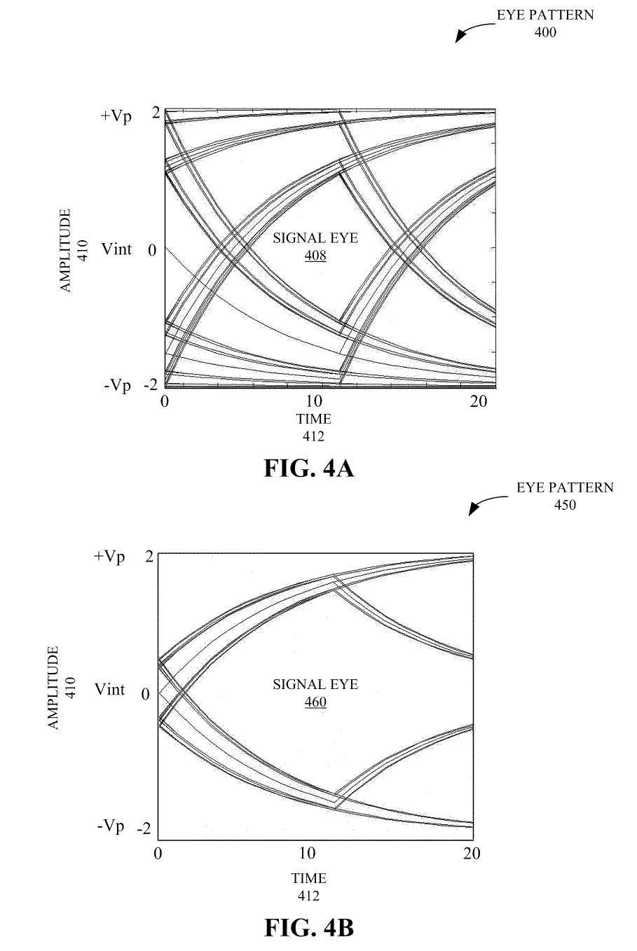

FIGS. 4A and 4B are eye patterns 400 and 450 that illustrate the extraordinary improvement in timing and voltage margins (collectively ‘error margins’) provided by the coding technique detailed here. Both diagrams are potted as amplitude 410 versus time 412 for physically similar channels. Eye pattern 400 depicts a simulation of a differential signaling technique that provides an open signal eye 408. Eye pattern 450 depicts a simulation of a two-to-five encoder, such as that illustrated in state diagram 50 (FIG. 1). Signal eye 460 is considerably higher and wider than signal eye 408, which means that eye pattern 450 provides vast improvements in both voltage and timing margins. Indeed, the timing margin of eye pattern 450 is about double that of eye 408.

The extraordinary increases in voltage and timing margin provided by the above-described coding technique facilitate considerable reductions in bit errors, increased speed performance, or both. These improvements require some coding redundancy. For example, two bits can be conveyed differentially on two pairs of lines, versus the five used to convey two bits in the embodiment of FIGS. 1-3.

The odd and even states in the foregoing example have different numbers of 0s and 1s. Therefore, the incoming codeword at any given time interval is unbalanced, and switching to the next codeword changes the number of symbols of each type. Switching between codewords with different numbers of 0s and 1s changes the drive current used to source the signal, and consequently introduces simultaneous-switching noise (SSN) in the supply voltage. SSN can adversely impact system performance. However, if the data rates are sufficiently high relative to the frequency response of the power-distribution network (PDN) supplying the drive current, the filtering effect of the PDN can dampen the data-dependent fluctuations. Moreover, any two adjacent codewords have the same number of 0s and 1s, so the code is balanced over two time intervals. Depending upon the filtering effects of the PDN, balancing the code over two time intervals may be sufficient to reduce SSN to a suitable level.

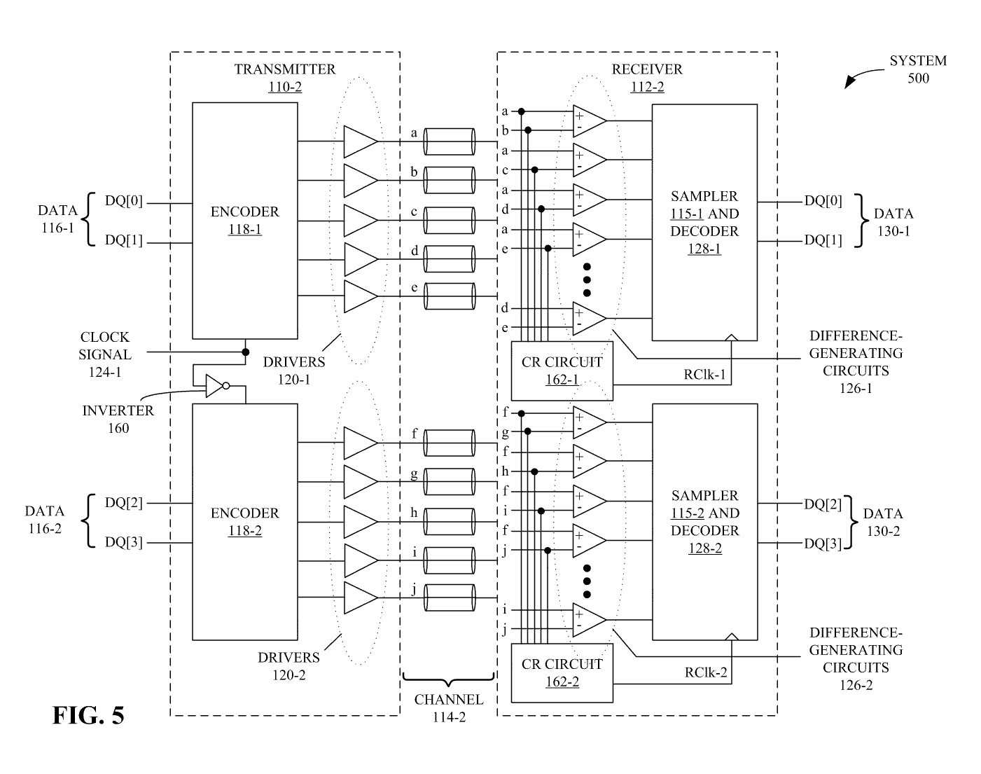

FIG. 5 presents a system 500 in accordance with another embodiment. System 500 is similar to system 200 (FIG. 2), with like-identified elements being the same or similar. System 500 duplicates the two-to-five encoder of system 200 (FIG. 2) to create a four-to-ten encoder. A half-rate clock signal 124-1 times encoder 118-1, and an inverter 160 inverts the sense of signal 124-1 to time encoder 118-2. Each encoder transitions from an odd state to an even state on rising clock edges and from an even to an odd state on falling edges. Inverting the sense of the clock signals for the two encoders thus maintains the encoders in opposite states. As a consequence, system 500 maintains an equal number of ones and zeros across channel 114-2 in each time interval. The resulting balanced code minimizes or eliminates SSN.

Another advantage of the encoding techniques detailed herein is that they support embedded clocking. That is, a clock signal for recovering the data can be sourced with the data. As noted previously, sensing an average voltage over five links produces relatively low and high voltages for the even and odd states. In FIG. 5, clock recovery circuits 162-1 and 162-2 sum the voltages on their respective links, and consequently sense transitions between odd and even states. Then, clock recovery circuits 162-1 and 162-2 generate respective receive clocks RClk-1 and RClk-2 from the sensed transitions between odd and even states. In some embodiments, clock signals RClk-1 and RClk-2 are sensed differentially, and the resultant clock is used to sample incoming codewords.

Clock signals RClk-1 and RClk-2 rise (fall) when state transitions from even to odd (odd to even), and are, therefore, indicative of state as well as timing. Thus, the decoders 128 can use the clock signals for initialization or during operation to determine whether codewords are of the odd or even families of states.

The encoders and decoders described above can be disposed on one or more integrated circuits. For example, transmitter 110-1 and receiver 112-1 (FIG. 2) may be included on a common integrated circuit for intra-chip communication. Alternatively, the transmitters and receivers can be on different integrated circuits, for example, to facilitate communication between a memory controller and a memory device.

Continuing the discussion of FIG. 2, transmitter 110-1 and/or receiver 112-1 may operate synchronously. For example, encoder 118-1 and/or decoder 128-1 may operate synchronously based on either or both edges in clock signals 124-1 and 124-2, respectively, which may be generated off-chip and/or on-chip (such as, using a phase-locked loop, one or more reference signals provided by a frequency reference, and a dedicated clock-forwarding link, or by recovering an embedded clock signal as illustrated in FIG. 5). Thus, the N data symbols DQ[1:0] in data 116-1 may be received by transmitter 110-1 at a given clock edge or during a given time interval (if there is a slight variation in the arrival times).

In the preceding embodiments, adjacent codewords are created by dividing one codeword into minority and majority symbol sets and encoding the data for the subsequent codeword into the majority symbol set while holding the minority set constant. In the example of state diagram 50 (FIG. 1), the majority symbol set alternates between 0s and 1s in the respective even and odd families of states, and the minority set includes but one symbol. In other embodiments, codewords have different numbers of symbols, and the minority symbol set in each codeword may include more symbols. Still other embodiments can employ codewords with equal numbers of symbol types. Furthermore, the exemplary embodiments express codewords using binary symbols, but the technique can be extended to employ up to K amplitude levels, such as those associated with K-PAM encoding. The two-to-five and four-to-ten encoding techniques can be extended to additional N-to-M encoding techniques (where M is greater than N).

While wired links are used as an illustration, in other embodiments the encoding/decoding technique may be applied to a wide variety of communications channels, including those with optical links. In these communications channels, data is encoded as a sequence of codewords. Symbols in each codeword can be communicated via separate sub-channels in an optical link, for example, using frequency-division multiple access. At a receiver, these symbols result in determinate sample values and indeterminate sample values. The determinate sample values may be used to minimize or eliminate intersymbol interference for particular sub-channels, and to decode the codewords.

The preceding description has been presented to enable any person skilled in the art to make and use the disclosed embodiments, and was provided in the context of a particular application and its requirements. Various modifications to the disclosed embodiments will be readily apparent to those skilled in the art, and the general principles defined herein may be applied to other embodiments and applications without departing from the spirit and scope of the present description. Thus, the present description is not intended to be limited to the embodiments shown, but is to be accorded the widest scope consistent with the principles and features disclosed herein. Moreover, the foregoing descriptions of embodiments have been presented for purposes of illustration and description only. They are not intended to be exhaustive or to limit the present description to the forms disclosed. Accordingly, many modifications and variations will be apparent to practitioners skilled in the art. Additionally, the above disclosure is not intended to limit the present description. The scope of the present description is defined by the appended claims.

What is claimed is:

1. A transmitter comprising:
an encoder circuit to encode data into consecutive M-symbol codewords that are associated with corresponding time intervals, wherein the encoder:
encodes first data as a first codeword in a first time interval, the first codeword including a first set of symbols of a first symbol type and a second set of symbols of a second symbol type; and
encodes second data in a second, subsequent codeword immediately following the first codeword in a next time interval, wherein the encoding of the second codeword encodes the second data in the first set of symbols and holds the second set of symbols constant, and wherein the second codeword is selected from a subset of possible M-symbol codewords that produces the same number of symbol transitions between the first codeword and the second codeword.

2. The transmitter of claim 1, wherein the first symbol set of symbols includes more symbols than the second set of symbols.

3. The transmitter of claim 2, wherein the first set of symbols consists of one symbol.

4. The transmitter of claim 1, wherein the second codeword includes a third set of symbols of the first symbol type and a fourth set of symbols of the second symbol type;
wherein the encoder encodes third data in a third codeword immediately following the second codeword in a third time interval; and
wherein the encoding of the third codeword encodes the third data in the fourth set of symbols and holds the third set of symbols constant.

5. The transmitter of claim 4, wherein the third codeword is selected from a subset of the possible M-symbol codewords that produces a fixed number of symbol transitions between the second codeword and the third codeword.

6. The transmitter of claim 5, wherein the same number of symbol transitions and the fixed number of symbol transitions are equal.

7. The transmitter of claim 1, wherein the first symbol type and the second symbol type represent logic zero and logic one, respectively.

8. The transmitter of claim 1, further comprising M drivers to coupled the encoder circuit to a communication channel having M single-ended links.

9. The transmitter of claim 8, wherein the encoder in instantiated on a first integrated circuit, and wherein the communication channel is to couple the M drivers to a receiver on a second integrated circuit.

10. A receiver comprising:
input nodes to receive data expressed as a series of codewords, each codeword including symbols of first and second symbol types, wherein the codewords in the series of codewords alternate between codewords in which the first symbol type is a minority symbol type and codewords in which the first symbol type is a majority symbol type;
difference-generating circuits, each having first and second comparison-circuit input terminals, coupled to corresponding nodes of a unique pair of the input nodes, and a comparison-circuit output terminal to provide a sensed signal responsive to a difference between the symbol types on the pair of input nodes, wherein the sensed signal is a high/low signal if the symbol types on the pair of input nodes are of the first and second symbol types and is an intermediate signal if the symbol types on the pair of input nodes are like symbol types;
a sampler having multiple sampler input terminals coupled to corresponding comparison-circuit output terminals to sample the high/low and intermediate signals for each codeword, wherein sampling the high/low and intermediate signals produces a minority of determinate samples and a majority of indeterminate samples for reach codeword; and
a decoder coupled to the sampler to receive at least the minority of determinate samples for each codeword, the decoder to decode the data from the minority of determinate samples for each codeword.

11. The receiver of claim 10, further comprising a sensor coupled to at least a subset of the input nodes, the sensor to provide an indication of the minority symbol type for at least one of the codewords.

12. The receiver of claim 11, wherein the sensor provides the indication to the decoder; and
wherein the decoder employs the indication to decode the data.

13. The receiver of claim 11, wherein the indication transitions for each codeword, the receiver further comprising clock-recovery circuitry to derived a receive clock signal from the indication.

14. The receiver of claim 13, wherein the sampler samples the high/low and intermediate signals for each codeword on edges of the receive clock signal.

15. The receiver of claim 10, wherein the sensed signals are analog voltages that range between a first voltage indicative of the first symbol type and a second voltage indicative of the second symbol type; and
wherein the intermediate sensed signals are between the first and second voltages.

16. A method for encoding data in successive codewords, each codeword representing M symbols at M symbol positions, the method comprising:
for each of a plurality of adjacent time intervals:
encoding first data as a current codeword in a current time interval, the current codeword including a set of logic zero symbols at a first set of symbol positions and a set of logic one symbols at a second set of symbol positions;
identifying a subset of possible M-symbol codewords that produces a fixed number of symbol transitions at the first and second sets of symbols positions; and
encoding second data as a subsequent codeword selected from the subset of possible M-symbol codewords that produces the fixed number of symbol transitions.

17. The method of claim 16, wherein one of the first and second sets of symbol positions has fewer positions than the other of the first and second sets of symbol positions.

18. The method of claim 17, wherein encoding the second data includes identifying which of the first and second sets of symbol positions has fewer positions and selecting the subsequent codeword to prohibit symbol transitions on the set of symbol positions having fewer positions.

19. The method of claim 17, wherein the one of the first and second sets of symbol positions having fewer positions has one symbol position.

20. A transmitter circuit comprising:
means for encoding a sequence of N-symbol data patterns into consecutive M-symbol codewords that are associated with corresponding time intervals, wherein M is greater than N, wherein, for a given codeword, a number of instances of a first symbol type in the M symbols is different than a number of instances of a second symbol type in the M symbols, and wherein, for a given pair of N-symbol data patterns, the means:
encodes a first of the N-symbol data patterns as a first codeword in a first time interval; and
encodes a second of the N-symbol data patterns as a second, subsequent codeword immediately following the first codeword in a next time interval, wherein the encoding of the second codeword is based on the first codeword, wherein information associated with the second of the N-symbol data patterns is encoded into at least some of the symbols in the second codeword that have a majority symbol type, which is the larger of the number of instances of the first symbol type and the number of instances of the second symbol type; and
M drivers, coupled to the means and to couple to a channel, which includes M links, wherein a given driver is to output a given symbol in the given codeword onto a given link.
